(19) United States
(12) Patent Application Publication
(10) Pub. No.: US 2001/0027014 A1
(43) Pub. Date: Oct. 4, 2001

(54) METHOD OF FABRICATING INTERCONNECT

(76) Inventor: SHIH-WEI SUN, TAIPEI (TW)

Correspondence Address: KNOBBE, MARTENS, OLSON & BEAR, 620 NEWPORT CENTER DRIVE, SIXTEENTH FLOOR, NEWPORT BEACH, CA, 92660

(21) Appl. No.: 09/228,435

(22) Filed: Jan. 11, 1999

(30) Foreign Application Priority Data
Nov. 21, 1998 (TW) 87119324

(51) Int. Cl. H01L 21/4763; H01L 21/44

(52) U.S. Cl. 438/675; 438/687; 438/641; 438/627

(57) ABSTRACT

A method fabricating an interconnect. A sacrificial layer is formed on a substrate. The sacrificial is patterned for form an opening, followed by filling the opening with a metal interconnect. The sacrificial layer is removed, and a barrier layer is formed to cover the metal interconnect and the substrate. The barrier layer is conformal to the surface profile of the substrate having a metal interconnect thereon. A dielectric layer is formed on the barrier layer.

### BACKGROUND OF THE INVENTION

1. Field of the Invention

The invention relates in general to a method of fabricating an integrated circuit, and more particularly, to a method of fabricating an interconnect.

2. Description of the Related Art

Using copper (Cu) to fabricate an interconnect in an integrated circuits provides advantages such as low resistivity, high melting point, and high electromigration resistance. In addition, the operation speed is improved with a copper interconnect. Compared to aluminum, an operation speed twice faster can be obtained. In a damascene process, a copper interconnect structure can not only reduce an RC delay time, but also reduce the static capacitance between interconnects. Therefore, to increase the integration level and conducting speed of a device, it becomes a trend to use copper for the fabrication of an interconnect.

It is easy for copper to diffuse into material comprising silicon and silicon oxide. Very often, a barrier layer is deposited before the formation of the copper to avoid the copper diffusion, so as to prevent a leakage current to occur between devices. As the fabrication process reaches a linewidth of 0.25 μm, the space for filling a copper is limited enough itself. With the formation of an additional barrier layer, the linewidth of the copper interconnect is further reduce. As a consequence, the resistance of the copper interconnect is increased greatly.

In the conventional fabrication method to fill an opening penetrating through an oxide layer, a chemical mechanical polishing (CMP) is performed after forming a copper layer. The copper layer remained on the oxide layer other than filling the opening is removed until the oxide layer is exposed. Since the copper is a relatively soft material, after the CMP process, some copper residue is remained on the oxide layer instead of being removed completely. The copper residue may diffuse through the oxide layer or other layers formed on top subsequently to cause problems such as a leakage current.

In addition, since material such as oxide has a relatively high dielectric constant, a parasitic capacitance or a cross talk between devices can be induced, especially when the linewidth is reduced. A dielectric layer having a dielectric constant k less than about 3 to 3.5 is used to suppress the above phenomenon. However, though the problems of parasitic capacitance and cross can be suppressed by using a dielectric layer with a low dielectric constant, other problems may occur. For example, an organic dielectric layer with a low dielectric constant is commonly. Both the organic dielectric layer and a commonly used photo-resist layer contain mainly carbon atoms. While etching the photo-resist layer by dry etching, the organic dielectric layer is easily to be ashed away together with the photo-resist layer. Thus, it is difficult to further pattern the dielectric layer.

Another method to fabricate copper interconnect is to deposit a copper layer, followed by patterning the copper layer. For example, using dry etching with an organic compound as an etchant to define copper layer, the free radicals of the organic compound are easily to agglomerate to form a polymer to cover the copper surface. The etch process is thus obstructed. If ligand molecules such as 1,1,1,5,5,5-hexafluoroacetylacetonate (hfac) are used to react with the copper for produce a volatile complex to etch the copper, the etching process thus becomes a counter reaction of a chemical vapor deposition process for forming the copper layer. Thus, etching and deposition of the copper layer coincide. While the reaction between the ligand molecules and the copper layer is over active, an undercut is caused at the bottom of the copper layer underlying the photo-resist layer. When a higher temperature is required to increase the volatility of the copper-ligand complex, an organic dielectric layer with a poor thermal stability is easily damaged.

Thus, by the conventional method, especially by the fabrication process with a linewidth of 0.25 μm, a copper interconnect formed by dual damascene has a large resistance due to the limited linewidth. The formation of a barrier layer further worsens the problem of the large resistance. The RC delay time is thus too long to effectively operate the device.

In the above method for fabricating a copper interconnect, after forming a copper layer to fill an opening within a dielectric layer, a CMP process is performed on the copper layer until the dielectric layer is exposed. Since the copper is very soft, it is very often that a copper residue is remained on the dielectric layer after the CMP process. The copper residue is easily to diffuse into the underlying dielectric layer or other layer formed subsequently. The diffusion of copper may further cause a leakage current between devices or components.

In addition, while etching a dielectric layer made of organic dielectric material with a low dielectric constant, problems such as damaging the dielectric layer due to the existence of copper layer, or a counter reaction of copper deposition may also occur.

### SUMMARY OF THE INVENTION

It is an object of the invention to provide a method of fabricating an interconnect. The method can be applied to a process with a linewidth of 0.25 μm to form an interconnect with an increased linewidth.

It is another object of the invention to provide a method of fabricating an interconnect. An organic dielectric material can be used for forming a dielectric layer without causing the problems caused by the prior technique.

To achieve the above-mentioned objects and advantages, a method of fabricating an interconnect. A planarized sacrificial layer is formed on a substrate. The sacrificial layer is patterned to form an opening. A metal layer is formed on the sacrificial layer and to fill the opening. A CMP process is performed on the sacrificial layer until the sacrificial layer is exposed. The sacrificial layer is removed. A conformal barrier layer is formed on the substrate and the remaining metal layer. A dielectric layer with a low dielectric constant is formed to on the barrier layer.

According to the above method, the metal layer is formed to fill the opening without the formation of a barrier layer. Therefore, the problem of linewidth reduced by the formation of the barrier layer is solved. The conductivity of the interconnect made of the metal layer is improved. A sacrificial layer is formed and defined to form the opening, so that the problems occurring while etching the dielectric layer with a low dielectric constant is solved. After CMP, even there are some residual metal layer remained on the sacrificial layer, since the sacrificial layer is removed afterwards, the residual metal layer is removed too. The leakage current caused by the residual metal layer is eliminated.

Both the foregoing general description and the following detailed description are exemplary and explanatory only and are not restrictive of the invention, as claimed.

### BRIEF DESCRIPTION OF THE DRAWINGS

FIG. 1 to FIG. 4 are cross sectional views showing a conventional method for fabricating an interconnect.

### DESCRIPTION OF THE PREFERRED EMBODIMENTS

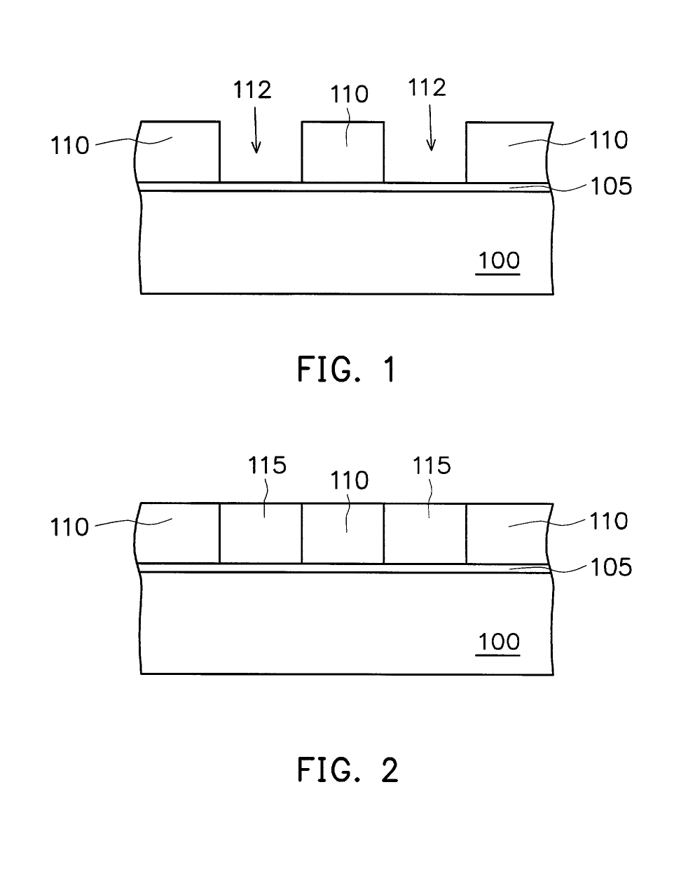

In FIG. 1, a sacrificial layer 110 is formed on a substrate 100. Preferably, the sacrificial layer 110 comprises a dielectric layer made of material of which the fabrication method is simple and the cost is low, for example silicon nitride. To advantage a following photolithography and etching process, preferably, the dielectric layer is planarized and selected from a dielectric material with a substantially high dielectric constant, typically, high than about 3 to 3.5.

A photolithography and etching process is performed on the sacrificial layer 110 to form an opening 112. In the case that the sacrificial layer 110 is made of silicon oxide, an isotropic etching can be used with a plasma comprising compounds containing carbon and fluorine.

In FIG. 2, a conductive material is formed to fill the opening 112, followed by polished by chemical mechanical polishing until the sacrificial layer 110 is exposed. An interconnect 115 is thus formed and fills the opening 112. The conductive material comprises metals such as copper, aluminum, and tungsten, while copper is more popularly used due to the property of low resistivity to enhance the operation speed of device. In the invention, unlike the prior technique, the interconnect 115 is formed without the formation of a barrier layer in advance. Thus, the linewidth of the interconnect 115 is not decreased in order to form a barrier layer. Consequently, a lower resistance is obtained to decrease the RC delay time and to increase the device operation speed.

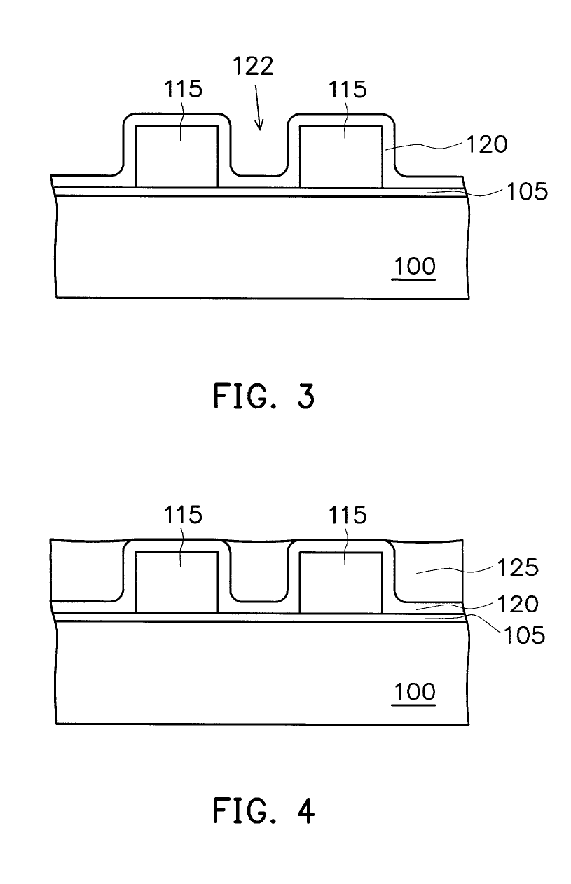

In FIG. 3, the sacrificial layer 110 is removed. As mentioned above, the sacrificial layer 110 can be selected from a dielectric layer with a substantially low dielectric constant, so that the problems such as ashing effect occuring in the prior technique is solved. When the sacrificial layer 110 is made of silicon nitride, a dry etching can be performed with a plasma comprising a compound containing carbon and fluorine, or alternatively, a wet etching process can be used also.

Since the sacrificial layer 110 is removed after the CMP process for forming the interconnect 115, even though there is any residual metal layer on the sacrificial layer 110, the residual metal layer 110 is removed together with the sacrificial layer 110. Therefore, the leakage current problem caused by diffusion of the residual metal layer is solved.

A conformal barrier layer 120 is then formed to cover the interconnect 115 and the substrate 100. The formation of the barrier layer is to prevent the interconnect 115 from diffusing and migrating into other layers formed subsequently. A very common material used for forming barrier layer includes a nitride layer formed by chemical vapor deposition, though other material may also be used.

A dielectric layer 125 is formed on the barrier layer 120. When more than one interconnect 115 is formed, or the interconnect 115 comprises elements being spaced with each other, the dielectric layer 125 is formed to fill spaces between interconnects or elements of interconnects. The dielectric layer 125 may be made of organic dielectric material with a substantial low dielectric constant such as parylene formed by, for example, spin-on coating or chemical vapor deposition.

The invention thus comprises at least the advantages as follows.

1. The interconnect is formed in an opening without the formation of a barrier layer in advance. The linewidth is thus not limited to the barrier layer. The problems of an increased resistance and a reduced operation speed in the prior art are thus solved.

2. By patterning a sacrificial layer with a substantially high dielectric constant instead of patterning a dielectric layer with a substantially low dielectric constant, the problems such as ashing effect occurring during etching is prevented.

3. The removal of the sacrificial layer after CMP process consequently remove any residual metal layer remained on the sacrificial layer. Therefore, a leakage current occur due to diffusion or migration of metal layer is eliminated.

4. When copper is used for forming interconnect, a damascene technique is employed instead of etching copper directly. Consequent problems with copper etching is avoided.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claimed is:

1. A method of fabricating an interconnect, comprising:
providing a substrate;
forming a sacrificial layer on the substrate;
forming an opening penetrating through the sacrificial layer;
forming a metal interconnect to fill the opening;
removing the sacrificial layer;
forming a barrier to cover the sacrificial layer; and
forming a dielectric layer on the barrier layer.

2. The method according to claim 1, wherein the sacrificial layer is made of a dielectric layer with a substantially high dielectric constant.

3. The method according to claim 2, wherein the dielectric constant is higher than about 3.0 to 3.5.

4. The method according to claim 1, wherein the metal interconnect is made of a material selected from a group consisting of including copper, aluminum, and tungsten.

5. The method according to claim 1, wherein the dielectric layer is made of a dielectric layer with a substantially low dielectric constant.

6. The method according to claim 5, wherein the dielectric constant is lower than about 3.0 to 3.5.

7. The method according to claim 1, wherein the metal interconnect is made of a material selected from a group consisting of including copper, aluminum, and tungsten.

8. A method of fabricating an interconnect, comprising:
forming a sacrificial layer on a substrate, the sacrificial having an opening exposing the substrate;
filling the opening with a metal interconnect; and
forming a dielectric layer to replace the sacrificial layer.

9. The method according to claim 8, wherein the metal layer comprises a refractory metal layer selected from a group consisting of titanium, cobalt, palladium, platinum, and nickel.

10. The method according to claim 8, wherein the sacrificial layer is made of a dielectric layer with a substantially high dielectric constant.

11. The method according to claim 10, wherein the dielectric constant is higher than about 3.0 to 3.5.

12. The method according to claim 8, wherein the metal interconnect is made of a material selected from a group consisting of including copper, aluminum, and tungsten.

13. The method according to claim 8, wherein the dielectric layer is made of a dielectric layer with a substantially low dielectric constant.

14. The method according to claim 13, wherein the dielectric constant is lower than about 3.0 to 3.5.

15. The method according to claim 1, wherein the metal interconnect is made of a material selected from a group consisting of including copper, aluminum, and tungsten.
